(19) United States
(12) Patent Application Publication
(10) Pub. No.: US 2006/0154385 A1
(43) Pub. Date: Jul. 13, 2006

(54) Fabrication pathway integrated metrology device

(76) Inventor: Ravinder Aggarwal, Gilbert, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/031,479

(22) Filed: Jan. 7, 2005

(51) Int. Cl. H01L 21/66

(52) U.S. Cl. 438/14; 438/16

(57) ABSTRACT

An in-line, non-freestanding substrate measurement system is integrated into the substrate fabrication pathway. One embodiment includes a metrology device integrated into a guided vehicle. Another embodiment provides a system for simultaneously measuring both sides of a substrate. A metrology device may be integrated into the front handling chamber of a process tool. Other embodiments provide methods for the measurement of substrates using pathway integrated metrology devices.

### FIELD OF THE INVENTION

The present invention relates generally to semiconductor fabrication, and more particularly to the use and placement of wafer inspection or metrology tools.

### BACKGROUND OF THE INVENTION

Semiconductor wafers or other such substrates are typically subjected to a number of processing steps as they progress through a variety of tools within a fabrication facility. For example, wafers that have been subjected to a process such as chemical vapor deposition are typically moved to another apparatus to be cleaned and dried and then transferred to yet another apparatus for additional processing steps, such as photolithography and etching, etc. The presence of contaminant particles on the surface of a wafer can lead to the formation of defects during the fabrication process. During this process, it is very important that the wafer be kept isolated from contamination. Therefore, the wafers are desirably moved between chambers in such a way as to minimize contamination of both the wafers themselves and the possibility of the cross contamination of chambers.

In furtherance of minimizing contamination, metrology devices, which detect contamination or otherwise measure wafer qualities, are often employed as quality control tools. For example, some metrology devices detect particulate contamination by measuring the number of particles on a wafer after it has been processed. Normally, a metrology device is located as a free standing tool or placed inside a process tool.

The cost of processing semiconductor wafers, always a prime consideration, is often evaluated by the throughput (e.g., wafers per hour) per unit of cost. Another measure of cost is the throughput per area of floor space, such that it is desirable to reduce the footprint of the apparatus employed. Related to both is the importance of reducing the capital cost of the equipment. Therefore, advancements that can improve the competitive edge by either measure are highly desirable.

Accordingly, a need exists for improved metrology schemes within a semiconductor fabrication facility.

### SUMMARY OF THE INVENTION

Preferred embodiments of the current invention describe a metrology device integrated into the wafer fabrication pathway as part of an in-line guided vehicle. Additional preferred embodiments of the current invention describe a metrology device integrated into the wafer fabrication pathway as part of a front handling chamber of a process tool. Alternate preferred embodiments provide a system for simultaneously measuring both sides of a substrate. Yet other embodiments provide methods for the measurement of substrates using pathway integrated metrology devices.

Among other advantages, preferred embodiments of these pathway integrated metrology devices offer more flexible and efficient tool utilization, decrease the lag time before defects and malfunctioning machinery are discovered, and have smaller footprints.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1A is a schematic overhead view of a fabrication floor, showing a metrology device integrated into a process tool loading platform, in accordance with one embodiment of the invention.

FIG. 1B is an overhead schematic view of a fabrication floor, showing a guided vehicle with an integrated metrology device, in accordance with another embodiment of the invention.

FIG. 2A shows a side perspective view of a guided vehicle with an integrated metrology device, in accordance with one embodiment of the present invention.

FIG. 2B shows a side perspective view of an automatically guided vehicle with an integrated metrology device, in accordance with one embodiment.

FIG. 2C shows a side perspective view of a personally guided vehicle integrated metrology device, in accordance with another embodiment.

FIG. 3A is a schematic side view of the guided vehicle of FIG. 2A docked with the front of a process tool with a metrology device in an undocked position relative to a process tool.

FIG. 3B is a schematic side view of the docked guided vehicle shown in FIG. 3A, the metrology device being docked with the process tool.

FIG. 3C is a schematic top view of the guided vehicle of FIG. 2A docked with the front of a process tool having two handling chambers, the guided vehicle including an integrated docked metrology device, in accordance with an embodiment of the present invention.

FIG. 4 is a schematic top view of an embodiment of the present invention, including a front handling chamber integrated metrology device located at a front docking port of a process tool having a single handling chamber.

FIG. 5 is a schematic top view of another embodiment, showing a front docking port integrated metrology device on a process tool having dual handling chambers.

FIG. 6 is a schematic side view of the front docking port integrated metrology device and process tool of FIG. 5.

FIG. 7 is a schematic top view of an integrated metrology device integrally mounted on the side of a front handling chamber of a process tool having two handling chambers, in accordance with another embodiment of the present invention.

FIG. 8 is a schematic side view of a double-sided scanning system, constructed, in accordance with an embodiment of the present invention.

FIG. 9 is a flowchart illustrating a method of measuring wafer qualities using a measuring device joined to a front handling chamber.

FIG. 10 is a flowchart of illustrating method of measuring wafer qualities using a fabrication pathway integrated metrology device, in accordance with an embodiment of the present invention.

FIG. 11 is a flow chart illustrating a method of measuring wafer qualities using a metrology device integrated with a guided vehicle, in accordance with another embodiment of the present invention.

### DETAILED DESCRIPTION OF THE PREFERRED EMBODIMENTS

One possible location of a metrology device is as a free standing tool on the floor of the fabrication facility. An off-line freestanding tool occupies facility floor space, a valuable commodity for which many processing machines are competing. The design of an off-line freestanding metrology tool requires the use of an often bulky support stand and handling platform, which occupies considerable clean room space. Therefore, reducing the footprint of an apparatus is advantageous.

An off-line freestanding metrology machine, by virtue of being separate from a processing tool, also necessitates exposing the wafer to extra handling. Additional unnecessary handling also subjects the fragile wafers to an increasing risk of accidents and contamination of the wafers. In an industry in which the speed of processing is directly related to output, these additional handling steps slow the fabrication line.

In addition, because a freestanding metrology tool is separate from a fabrication tool, the lag time between when the wafers leave the processing machine and arrive at the off-line freestanding metrology tool can result in considerable delays and waste because corrective action is not taken immediately after processing. For instance, if the machine is contaminated or operating incorrectly, by the time the freestanding metrology tool detects a catastrophic level of defects, multiple wafers will have been defectively manufactured. The quicker a metrology device detects a malfunctioning machine, the sooner the problem can be fixed, thus lowering the fabrication costs. Therefore, wafer fabrication system improvements which decrease this lag time are highly desirable.

Another possible pathway location for a metrology tool is in place of one of the processing chambers, such as occupying one of the ports of a multi-chamber process tool or “cluster tool.” Although the placement of the metrology tool as a module on a cluster tool would solve some of the problems associated with freestanding machines, this internal location creates new difficulties.

One problem with a cluster tool port location is that the metrology device occupies one of the ports to the exclusion of other devices. Therefore, not all ports of the cluster tool can be occupied by process modules. This exclusionary effect can be of great detriment to throughput in general, especially in situations involving a sequential process where all ports need to be occupied by process modules. Another problem with internal process chamber placement of the metrology device is that utilization of the metrology tool is limited to the cluster tool in which it is housed.

In response to the inadequacies of the aforementioned potential metrology device locations, embodiments described herein are provided to measure substrates in-line as they move through a substrate fabrication pathway. Embodiments of the invention include integrating the substrate measurement device with a cart, such as a personally-guided vehicle or an automatically-guided vehicle. Embodiments of the invention further include the integration of a substrate measurement device with a process tool's loading platform or front end handling chamber.

Among other advantages, these pathway integrated tools offer more flexible and efficient tool utilization, decrease the lag time before defects and malfunctioning machinery are discovered, and have smaller footprints. Preferred embodiments of the present invention employ an in-line pathway integrated metrology device in order to maximize the efficient utilization of existing pathway tools and allow more space to be available for other components of the fabrication pathway.

A feature of the preferred embodiment is the facilitation of a quick analysis of whether a machine is working properly, without the unnecessary “lag time” and wasted substrates associated with the off-line placement of metrology devices.

Another feature described herein allows both sides of the substrate to be analyzed simultaneously once the substrate is in the substrate measurement device, without the need for moving or shifting of the substrate. Not only is this double-sided detection quicker, but because the substrate is subjected to less movement, the risk of damage to the substrate is reduced. These and other advantages are described in the embodiments below.

“Metrology device” refers to any device designed to detect qualities such as particles, defects, layer thickness, etc. of substrates in process.

“Guided vehicle” refers to a vehicle designed to travel between process tools in a fabrication facility and can refer to either an automatically or a manually guided vehicle. Conventionally, such guided vehicles are designed for carrying cassettes (FOUPS) of substrates among process tools and storage locations.

The “front end interface loading platform” or “FEI” is the front interface section of a process tool where substrates are loaded into and unloaded from a process tool. The “FEI” includes the “front docking ports” with which substrate cassettes mate.

“In-line pathway” refers to the direct and efficient pathway which materials being processed travel from one process tool to another process tool in a fabrication facility. The “in-line pathway” includes the path that substrates travel in the interior of a process tool.

An “off-line pathway” is a pathway between two process tools, in which sequential processes are conducted, that substantially deviates from the direct and efficient pathway between process tools.

“In-line metrology device” refers to a metrology device which is located along the in-line pathway.

“In-line guided vehicle” refers to a guided vehicle which travels along the in-line pathway.

“Exterior of the load lock” refers to components of a process tool, not including the load lock chambers themselves, which are located between the front docking ports and a load lock chamber. “Exterior of the load lock” includes the front docking ports and any device, such as a cassette, operably joined with the front docking ports.

A “front handling chamber” refers to the front-most handling chamber of the process tool interior to a loading platform or front docking ports. The front handling chamber refers to the wafer handling chamber in embodiments having only one handling chamber. In embodiments having two handling chambers, located exterior and interior of the load lock chamber respectively, the front handling chamber refers to the handling chamber which is exterior of the load lock. In alternate embodiments the front handling chamber refers to the “atmospheric front end” (AFE) handling chamber located directly interior of the front docking ports.

The “side of the front handling chamber” refers to either of the two vertical faces of a “front handling chamber” chamber which do not directly join with either a front docking port or a load lock chamber.

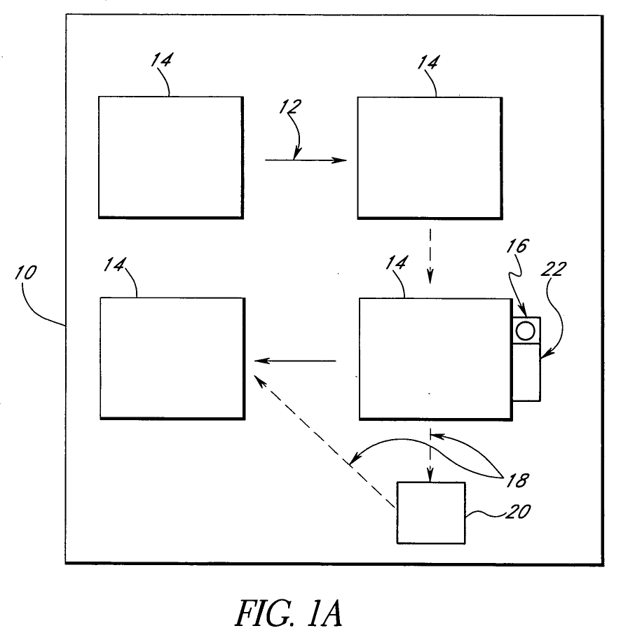

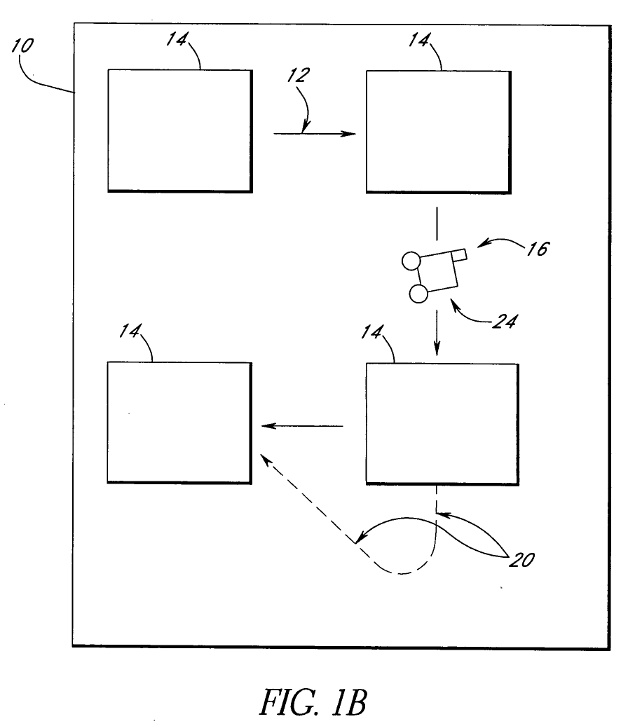

Referring to FIG. 1A, a fabrication facility 10 is shown with an in-line fabrication pathway 12, comprising a series of process tools 14. For example, the process tools 14 could comprise photolithography, etch, chemical vapor deposition (CMP) and/or deposition tools. The in-line fabrication pathway 12 is the direct and efficient pathway along which a substrate or wafer (not shown) moves for sequential steps as it is being fabricated. This in-line fabrication pathway 12 includes the path of the wafer through an actual process tool 14 in addition to the path on which the wafer travels en route from one process tool 14 to another process tool 14. Preferably, a metrology device 16 is integrated into this in-line fabrication pathway 12 through joining the device to a front handling chamber (not shown), either selectively or permanently mounted, to allow the wafer to remain on the in-line fabrication pathway 12, without requiring that the wafer be diverted onto an off-line pathway 18, as would be necessary if the wafer were delivered to off-line device 20. Here, the metrology device 16 is shown located on the front end interface (FEI) loading platform 22.

The metrology device 20 is preferably integrated into the in-line fabrication pathway 12 through integration with a front docking port (not shown). In another embodiment, shown in FIG. 1B, the metrology device 16 is integrated into the in-line fabrication pathway 12 by locating the metrology device 16 on a guided vehicle 24, which has the capability of moving between process tools 14 and conducting measurement while preferably remaining on the in-line fabrication pathway 12.

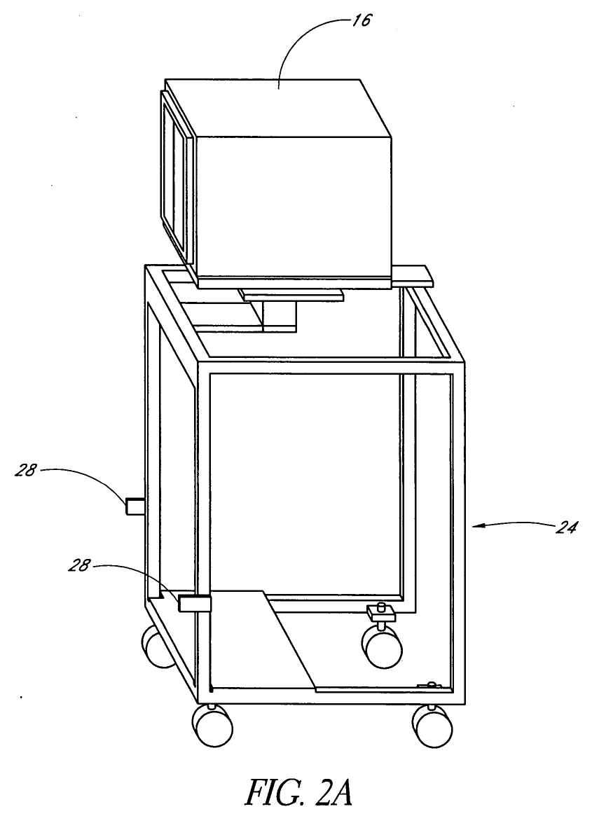

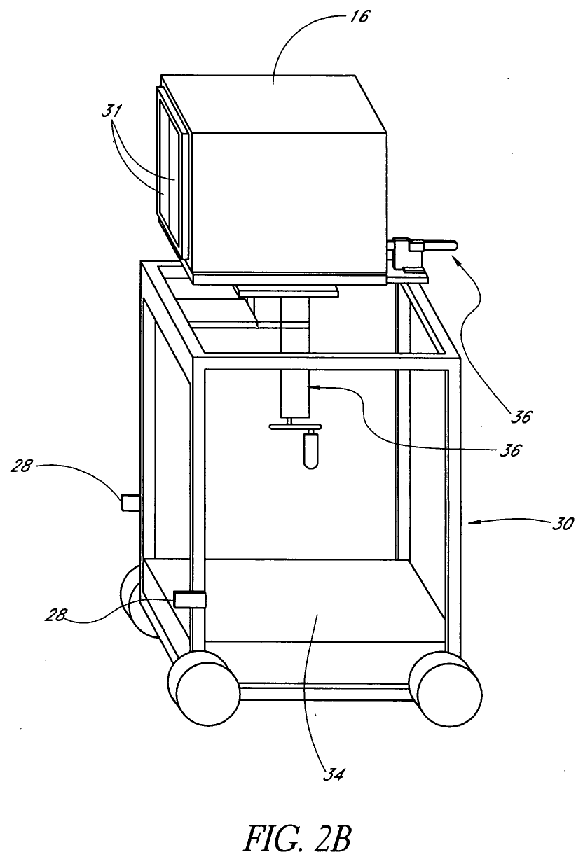

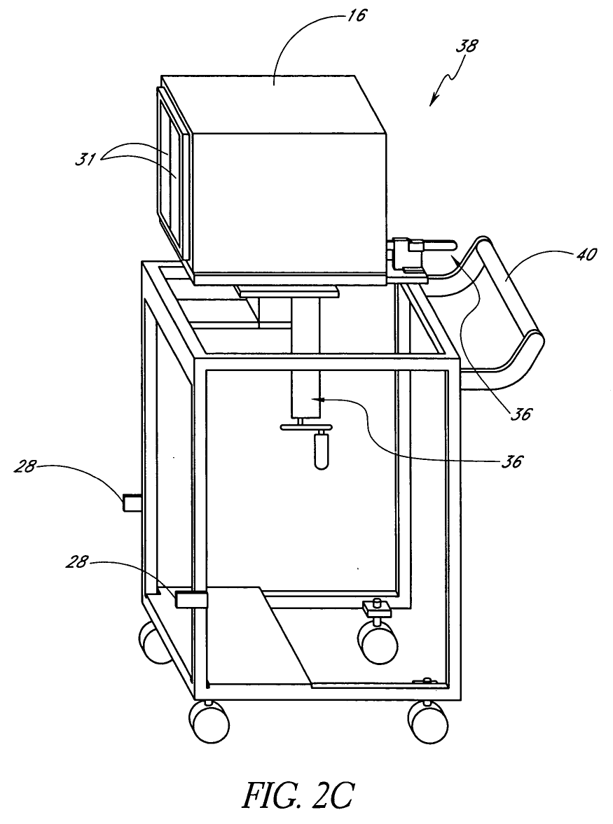

Referring now to FIG. 2A, the metrology device 16 is shown integrated into the guided vehicle 24. Preferably, the guided vehicle 24 is capable of docking with the process tool 14 using a docking mechanism 28.

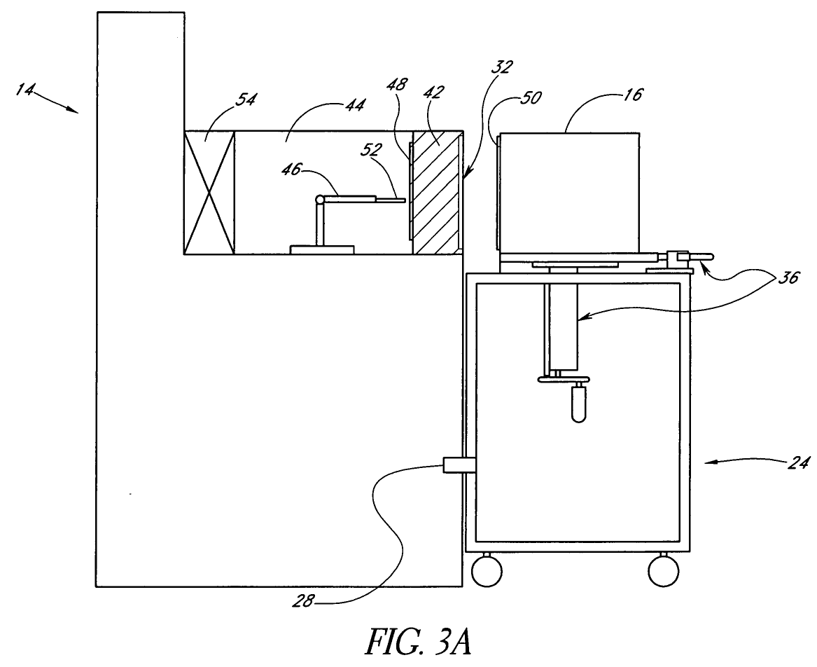

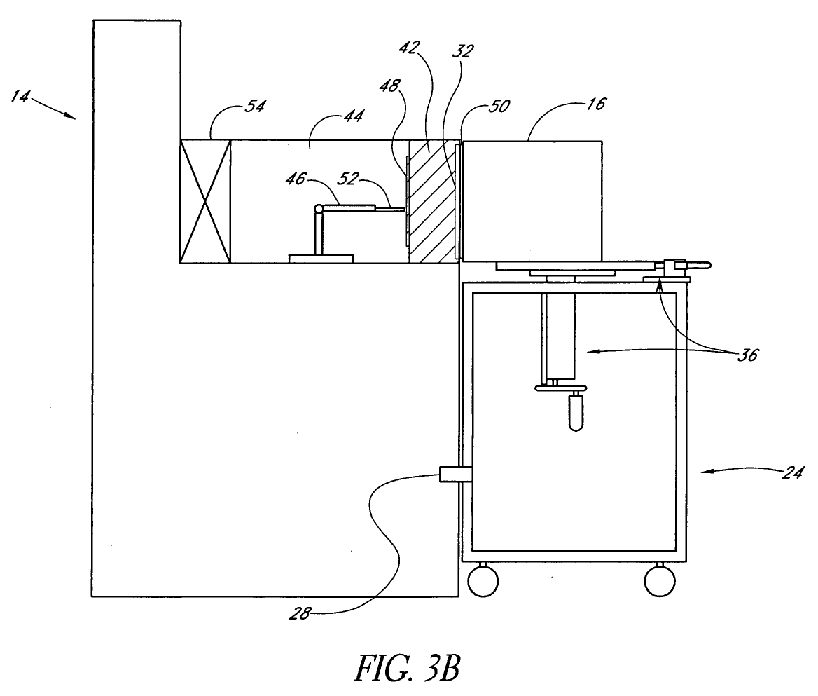

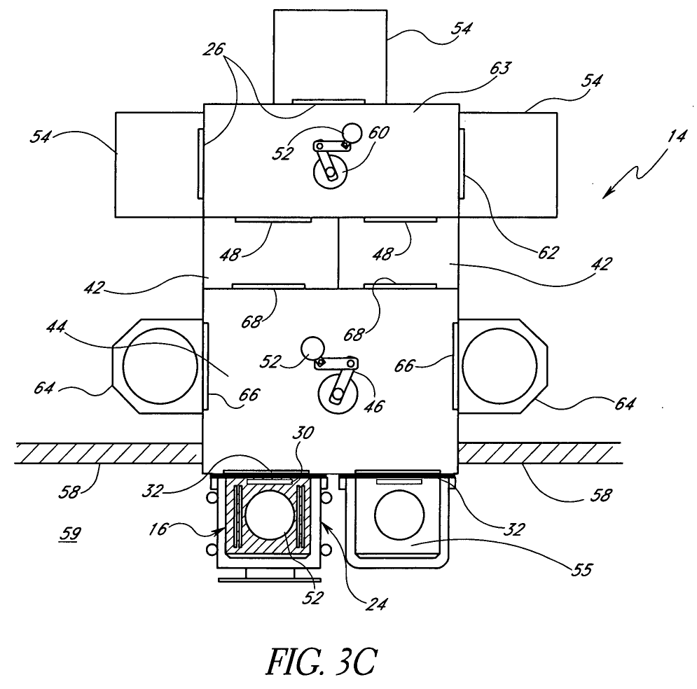

In a particular arrangement, the guided vehicle can be an automatically guided vehicle (AGV) 30 as shown in FIG. 2B. The metrology device 16 is positioned on the guided vehicle 30 such that the metrology device doors 31 can mate with a front docking port 32 of the process tool 14 (see FIG. 3B). Preferably, the AGV 30 includes a motor 34, shown schematically only. In addition, the guided vehicle preferably has a positioning mechanism 36 which includes mechanisms for both horizontally and vertically positioning the metrology device 16. The positioning mechanism 36 can be either manually or automatically operated (FIGS. 2B and 2C).

In another arrangement, the guided vehicle is a personally guided vehicle (PGV) 38, as shown in FIG. 2C, which includes a guidance handle 40.

In an embodiment illustrated by FIGS. 3A, 3B and 3C the guided vehicle integrated metrology device 16 is configured to dock with a front docking port 32 of a process tool 14. FIG. 3A shows an embodiment lacking the front handling chamber, in that the metrology device 16 docks directly with a load lock 42. Referring now to FIGS. 3A and 3B, the process tool 14 preferably has a front handling chamber 44 located further interior relative to the front docking ports 32. FIG. 3A illustrates the guided vehicle 24 docked with the process tool 14 via the docking mechanism 28, while the metrology device 16 itself in an undocked position with respect to the docking port 32. A front conveyance, here a robot arm 46, is also located inside the front handling chamber 44 in such a position as to facilitate access to the load lock 42 via load lock interior closure 48. The load lock 42 preferably contains a load lock rack (not shown) and, also, a load lock conveyance, such as a robot (not shown) preferably located inside the load lock 42 in order to facilitate transfer of substrates between the load lock 42 and the metrology device 16. Preferably, the metrology device 16 is positioned on the guided vehicle 24 to place the metrology device doors 31 in a position to dock with the front docking port 32. The guided vehicle 24 also preferably has the positioning mechanism 36 in order to adjust the position of the metrology device 16 with respect to the docking port 32. The positioning mechanism 36 may be manually or automatically operated. A wafer 52 is shown on the end of the front robot arm 46.

FIG. 3B shows alternate arrangement of the embodiment shown in FIG. 3A in which the metrology device 16 itself is docked with the docking port 32, in addition to the guided vehicle 24 itself being docked to the process tool 14 as shown in FIG. 3A.

The operation of the embodiment shown in FIG. 3B begins with the guided vehicle 24 docking with the process tool and the metrology device 16 docking with docking port 32. The wafer 52 is then removed from one of the process chambers 54 by the front robot arm 46, the load lock interior doors 48 open, and the wafer 52 is then transferred into the load lock chamber 42. The load lock chamber interior closure 48 close and the metrology device doors 31 (FIG. 2C) then open. A load lock robot (not shown) preferably located in the load lock 42, then places the individual wafers 52 into the metrology device 16, which is integrated with the guided vehicle 24. Once the wafer 52 is inside the metrology device 16, qualities of the wafer 52 are measured, preferably optically. After the wafer 52 is scanned, the wafer 52 is removed from the metrology device 16 by the load lock robot (not shown) proximate to the front docking port 32 and replaced in a cassette (not shown), or a FOUP. The cassette can then be moved, manually or using an exterior robot arm (not shown), to another component of the fabrication system.

FIG. 3C illustrates an embodiment having both a rear handling chamber 63, including a rear conveyance, here robot 60, therein, and the front handling chamber 44 with the front robot 46 located therein. FIG. 3C also shows the metrology device 16 in a docked position with respect to the docking port 32. A cassette 55 is preferably docked to the remaining docking port 32. Preferably, two buffer stations 64 are joined to the sides of the front handling chamber 44 and are selectively closeable via buffer station doors 66. The two load locks 42 are also preferably joined to the front handling chamber 44 providing selectively closeable passageways between the front handling chamber 44, preferably an atmospheric front end (AFE), and the rear handling chamber 63, preferably a wafer handling chamber (WHC). The load locks 42 can be selectively isolated from both the front handling chamber 44 and the rear handling chamber 63 via the load lock exterior 68 closures and the load lock interior closure 48. The rear robot 60 is also located in the rear handling chamber 63 so as to be capable of accessing the load locks 42 and the process chambers 54, which are joined to the rear handling chamber 63 via the process chamber closures 62. Also, preferably a clean-room wall 58 shown in FIG. 3C is placed flush with the front face of the process tool 14, but in alternate arrangements it should be understood that the clean-room wall can be placed so that a greater portion of the process tool protrudes from the wall into the clean room 59.

The operation of the embodiment shown in FIG. 3C proceeds in a similar fashion to the operation of FIG. 3B, except the wafers 52 must be carried by the rear robot 60 to the load lock chambers 42 and then through an additional chamber, the front handling chamber 44, en route to the metrology device 16. Also, the wafers 52 may be stored in the buffer stations 64 before and after being measured in the metrology device 16.

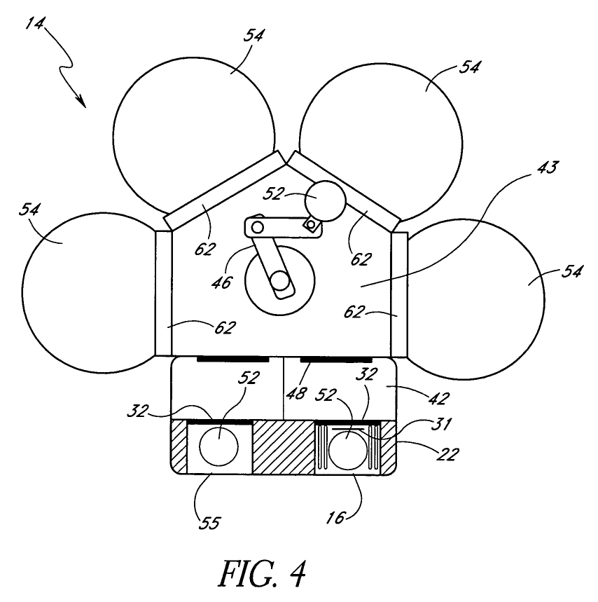

In an embodiment shown in FIG. 4, the metrology device 16 is operatively joined with the process tool 14 having the rear handling chamber 63 connected via the closures 62 to the process chambers 54. The front robot 46 is configured and programmed to be capable of accessing both the process chambers 54 and the load locks 42. The metrology device 16 is integrated into the front handling chamber through docking with the front docking ports 32 and preferably resting on the front end interface (FEI) load platform 22. By occupying one of the front docking ports 32, the metrology device 16 preferably occupies a port that would otherwise be capable of docking with the cassette 55. The metrology device doors 31 and the front docking ports 32 are selectably openable and positioned so that they can be accessed by the load lock robot preferably located inside the load lock 42.

In the preferred embodiment shown in FIG. 4 the wafer 52 is taken out of the processing chamber 54 of the process tool 14 by the front robot 46. The front robot 46 then transfers the individual wafers 52 into a load lock chamber 42 after the interior load lock closures 48 have opened. The load lock interior closures 48 then close and the metrology device doors 31 open. At this time, the load lock robot arm (not shown) conveys the wafer 52 to a measurement device, here the metrology device 16 joined with the front handling chamber on the front end interface loading platform (FEI) 22.

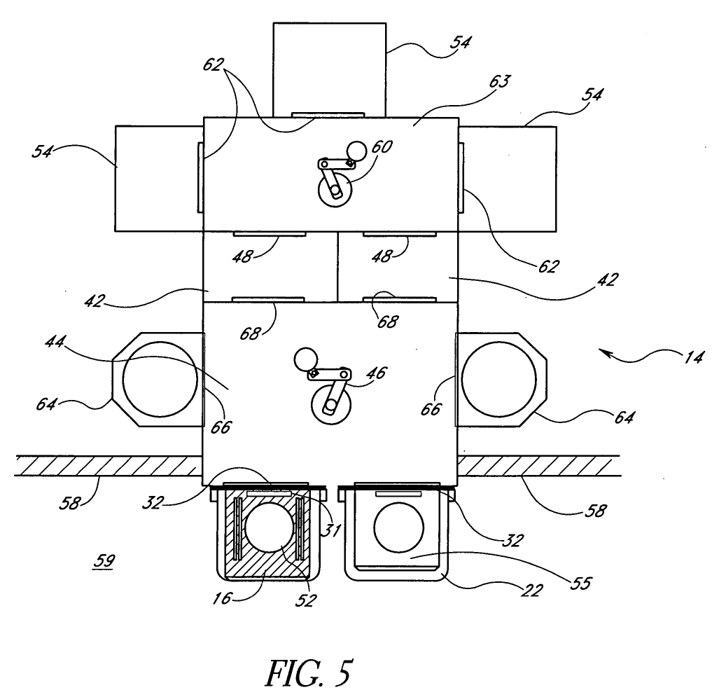

In yet another embodiment shown in FIG. 5, the metrology device 16 is shown joined with the front handling chamber 44 via the docking port 32 as in FIG. 4, but the process tool 14 shown in FIG. 5 also has the rear handling chamber 63. The structure of the process tool 14 shown in FIG. 5 is similar to the process tool shown in FIG. 3C except in FIG. 5 the metrology device 16 is shown integrated with a docking port 32 by locating the metrology device 16 on the front end interface loading platform (FEI) 22, rather than on a cart. The process tool 14 has the front robot 46 positioned in the front handling chamber 44 so as to allow access to the metrology device doors 31 located at one of the front docking ports 32. The clean-room wall 58 is also preferably placed flush with the front face of the process tool 14, but in alternate embodiments it should be understood that the clean-room wall can be placed so that a greater portion of the process tool 14 protrudes into the clean room 2.

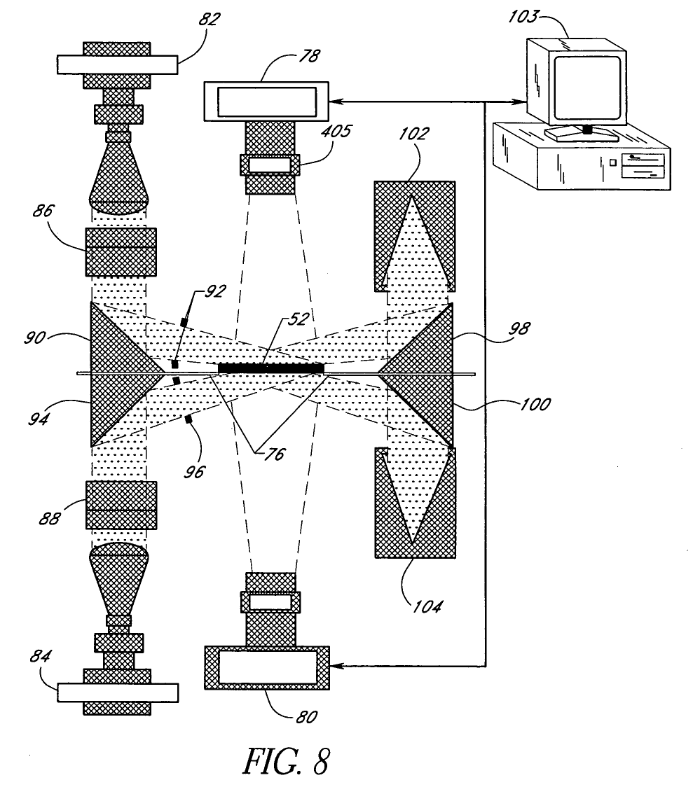

In alternate preferred embodiments, the wafer is scanned using the simultaneous double sided optical scanning system shown in FIG. 8.

Although two buffer stations 64 are shown in FIG. 5, alternate arrangements employ only one buffer station or, in yet other arrangements, completely lack these buffer stations. In addition, although two load locks 42 are shown, alternate arrangements can employ only one load lock. Similarly, although multiple process chambers 54 are shown, alternate arrangements employ at least one process chamber.

In an alternate arrangement, the front robot arm first places a wafer in a holding station, such as an open cassette or FOUP, prior to the front robot arm placing a wafer in the metrology device.

In yet another arrangement, after qualities of the wafer are measured in the metrology device, the front robot arm places the wafer in a holding station, such as an open cassette or FOUP, to await automatic or manual transfer to another component of the fabrication system.

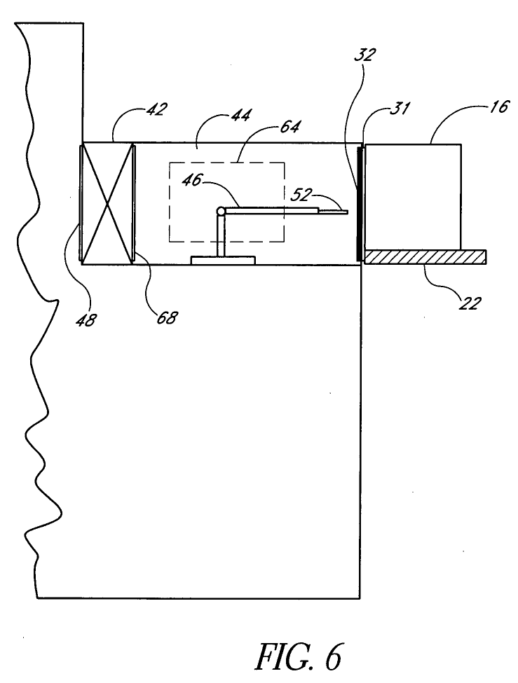

FIG. 6, shows a side cross-section of a front section of the process tool shown in FIG. 5, the shown portion starting from the load lock chambers 42 and continuing to the front end interface loading platform 22.

The operations of the embodiment shown in FIGS. 5 and 6 preferably begins with the wafer 52 being taken out of the process chamber 54 and into the rear handling chamber 63 by the wafer handling chamber rear robot arm 60 (not show in FIG. 6). The interior load lock closures 48 then open and the rear robot arm 60 transfers the wafer 52 into the load lock 42. The interior load lock closures 48 close and the load lock exterior closures 68 then open. The front robot arm 46 moves the wafer 52 from the load lock 42 into the front handling chamber 44. The metrology device doors 31 then open and the front robot arm 46 places the wafer 52 in the metrology device 16 located on the front end interface (FEI) loading platform 22 in a position that could otherwise be occupied by the wafer cassette 55. The wafer 52 is placed interior to the metrology device 16 on the wafer holder (not shown). The metrology doors 31 close and the wafer 52 is scanned. The scanning of the wafer 52 produces a signal that is processed and interpreted by an external computer (not shown). After scanning, the metrology device doors 31 are opened and the front robot arm 46 removes the wafer 52 from the wafer holder. The wafer 52 is then placed in a suitable storage location, such as the cassette 55 or, in an alternative embodiment, in the buffer station 64.

In another variation of the operational sequence above, the front robot 46 can place the wafer 52 in the buffer station 64 prior to transferring the wafer 52 into the metrology device 16.

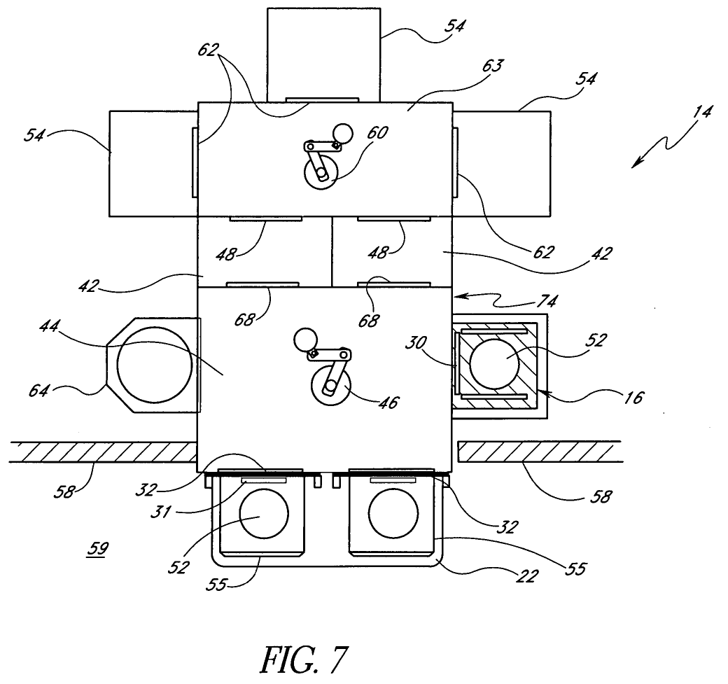

In an alternative embodiment illustrated by FIG. 7, a process tool 14 is shown similar in structure and operation to the process tool 14 shown in FIG. 5, except the metrology device 16 is integrated into the front handling chamber 44 by being integrated into a side of the front handling chamber 44, similar to the buffer station 64. In addition, since in FIG. 7 the metrology device 16 is no longer occupying the front docking port 32 as in FIG. 5, then two cassettes 55 may be docked with the front docking ports 32. Also, the front robot 46 is configured and programmed to transfer the processed wafer 52 from the load locks 42 to the side mounted metrology device 16. After the wafer 52 is scanned in the metrology device 16, the wafer 52 can be placed in a suitable storage location, including either the cassette 55 or the buffer station 64.

The operation of the embodiment shown in FIG. 7 preferably begins with the metrology device doors 31 opening, and the front robot 46 placing the wafer 52 on the wafer support (not shown) interior to the metrology device 16 for the measuring of wafer features. The metrology doors 31 close and the wafer 52 is the scanned. The scanning of the wafer 52 produces a signal that is processed and interpreted by the external computer (not shown). After scanning, the metrology device doors 31 are opened and front robot 46 removes the wafer 52 from the wafer holder.

Referring now to FIG. 8, a schematic of the simultaneous double sided optical scanning system employed in certain preferred embodiments is provided. The wafer 52 is placed on a wafer support 76 preferably configured to support the wafer substantially by the edges only in order to leave substantially all of both the top and bottom surfaces of the wafer 52 exposed for scanning. A top camera 78 is mounted above the wafer 52 so as to view the top surface of the wafer 52, while a bottom camera 80 is mounted below the wafer 52 in order to view the bottom surface of the wafer 52. A top light source 82 and a bottom light source 84, each having beam shaping optics 86 and 88 respectively, are located so as to not directly shine light on the wafer surface. Instead, a first top triangular mirror 90 is configured to reflect the light from the top light source 82 through a top illumination mask 92 and onto the top wafer surface so that the light strikes the wafer 52 at an angle. Similarly, a first bottom triangular mirror 94 is configured to reflect the light from the bottom light source 84 through a bottom illumination mask 96 and onto the bottom wafer surface so that the light strikes the wafer 52 at an angle. On the opposite side of the light sources 82 and 84 are a second top triangular mirror 98 positioned to receive light reflecting off the top surface of the wafer 52 and a second bottom triangular mirror 100 positioned to receive the light reflecting off the bottom surface of the wafer 52. A top light trap 102 is positioned to capture the light reflected off the second top triangular mirror 98, while a bottom light trap 104 is positioned to capture the light reflected of the second bottom triangular mirror 100. In addition a computer 103 is operatively connected to the top camera 78 and the bottom camera 80, the computer having software enabling the computer to measure qualities of each wafer surface simultaneously.

The path of the light in the bottom surface scanning system shown in FIG. 8 preferably begins at the bottom light source 84. The light is projected through the beam shaping optics 88 which reflect the light at the first bottom triangular mirror 94. The reflected light then passes through the bottom illumination mask 96 and strikes the wafer 52 which in turn reflects the light to the second bottom triangular mirror 100. The second bottom mirror 100 then reflects the light into the light trap 104. The bottom camera 80 detects an image produced by the light striking the bottom surface of the wafer 52. This image is then electronically transmitted to the computer 103 which interprets and processes the images and outputs useful measurement data, such as the condition of the surface of the wafer 52.

The path of the light in the top surface scanning system begins at the light source 82. The light is projected through the beam shaping optics 86 which reflect the light at the first triangular mirror 90. The reflected light then passes through the top illumination mask 92 and strikes the wafer 52 which in turn reflects the light to the second top triangular mirror 98. The mirror 98 then reflects the light into the light trap 102. The top camera 78, which is positioned above where the wafer 52 is supported, detects the image produced by the light striking the top surface of the wafer 52. This image is then electronically transmitted to the computer 106 which interprets and processes the images and outputs useful measurement data. Preferably, the scanning of both wafer surfaces occurs generally simultaneously.

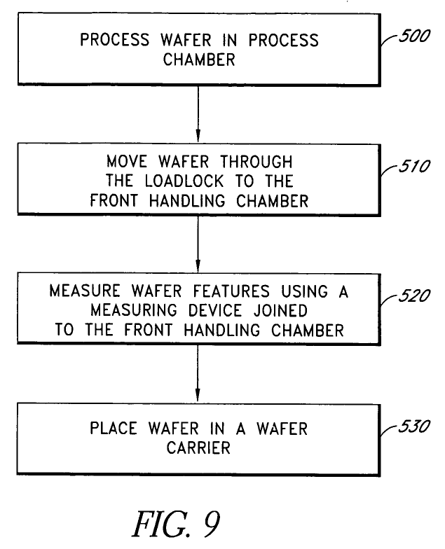

Referring to FIG. 9, a method of measuring wafer features using an in-line integrated metrology device is shown. The wafer is first processed 500 in the process chamber of the process tool. Then, the wafer is moved 510 through the load lock to the front handling chamber. Next, wafer features are measured 520 using the measuring device joined to a front handling chamber. The wafer is then placed 530 in a wafer carrier.

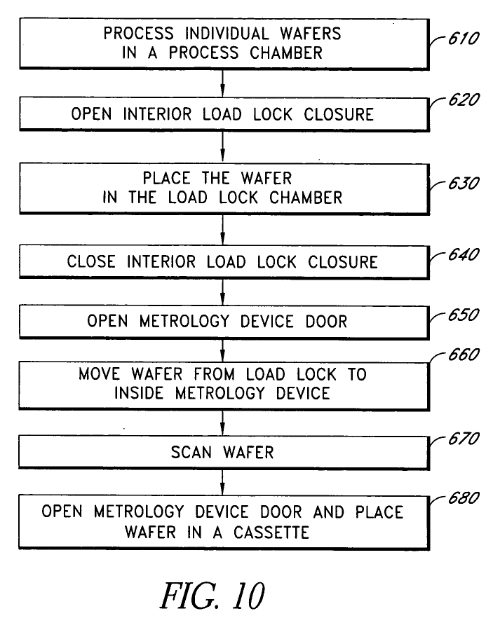

An embodiment of the present invention shown in FIG. 10 illustrates a method of measuring the wafer using the metrology device integrated with the front handling chamber. First, the individual wafers are processed 610 in the process chamber of a process tool. Next, the interior load lock closure opens 620 and the wafer is placed 630 in the load lock chamber, preferably using the rear robot. Then, the interior load lock closure closes 640. Next, the metrology doors open 650 and the wafer is moved 660 from the load lock to inside the metrology device, preferably using the load lock robot. The wafer is then scanned 670 in order to measure qualities of the wafer. After scanning, the metrology device doors are opened 680 and the wafer is preferably placed in the cassette or other suitable storage location, preferably using the front robot. Preferably, both sides of the wafer are scanned simultaneously, preferably using the front robot.

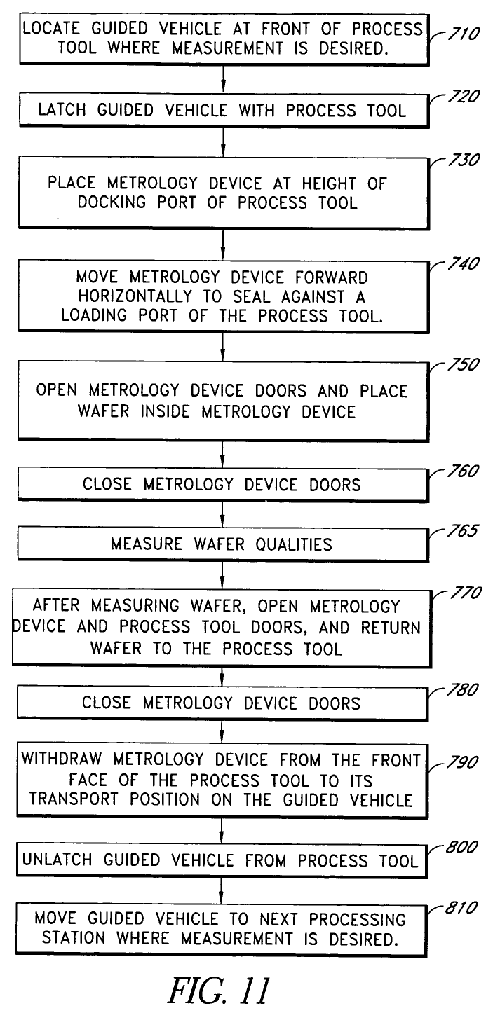

With reference to FIG. 11, a method of measuring wafer features using the guided vehicle integrated metrology device is shown. The guided vehicle is first located 710 at the front of the process tool where measurement is desired. The guided vehicle is then latched 720 into place. The metrology device is placed 730 at the height of the docking port of the process tool, preferably using a positioning mechanism. Next, the metrology device is preferably moved 740 forward horizontally using the positioning mechanism in order to seal against the loading port of the process tool. The metrology device doors are opened 750 and the wafer is then placed inside the metrology device, preferably using a front robot. Next, the metrology device doors are closed 760. The features of the wafer are measured 765, preferably by simultaneously scanning both sides of the wafer. After measuring, the metrology device doors are opened 770 and the wafers are returned into the process tool, preferably using the front robot. The metrology device doors are then closed 780. Next, the metrology device is withdrawn 790 from the front face of the process tool to its transport position on the guided vehicle. The guided vehicle is then unlatched 800 from the process tool and, then, the guided vehicle is preferably moved 810 to the next processing station on the fabrication facility floor where measurement is desired.

Preferably, in most embodiments, after the wafer has been optically scanned in the metrology device, the front robot arm moves the wafer to the FOUP or another form of cassette. The cassette is then moved by an external robot arm (not shown) or, in an alternative arrangement, manually, for transfer to another component of the fabrication system via a transport.

Among other advantages, these pathway integrated tools offer more flexible and efficient tool utilization, decrease the lag time before defects and malfunctioning machinery are discovered, and have smaller footprints.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications thereof. Thus, it is intended that the scope of the present invention herein disclosed should not be limited by the particular disclosed embodiments described above, but should be determined only by a fair reading of the claims that follow.

1. A wafer fabrication system, comprising:
a wafer processing tool including a front handling chamber and at least one processing chamber and a load lock chamber located between the front handling chamber and the processing chamber; and
a non-destructive metrology device configured as a module operatively joined with the front handling chamber.

2. The wafer fabrication system according to claim 1, further comprising at least one load lock chamber located between the front handling chamber and the processing chamber wherein the front handling chamber comprises a chamber located between the load lock and the front docking ports and the metrology device is operatively joined to the front handling chamber.

3. The wafer fabrication system according to claim 2, wherein the metrology device is removably joined to the front handling chamber.

4. The wafer fabrication system according to claim 1, wherein a wafer holder internal to the metrology device is configured to support the wafer horizontally by its edges only, so that substantially all of both sides of the wafer are exposed.

5. The wafer fabrication system according to claim 4, wherein the metrology device optically measures qualities of a silicon wafer by simultaneously measuring both sides of the wafer without necessitating the wafer be subjected to additional movement for this purpose.

6. A fabrication system for measuring a workpiece comprising:
a process tool as an in-line component of a fabrication pathway, the process tool having a front docking port located at the front interface of a process tool;
a vehicle which moves between the process tools where measurement is desired;
a metrology device integrated into the vehicle;
a workpiece holder interior to the metrology device; and
a conveyance proximate to the metrology device, the conveyance configured to place the workpiece in the portable metrology device.

7. The fabrication system of claim 6, wherein the vehicle is a guided vehicle which moves between process tools so that the guided vehicle may be shared in-line along the fabrication pathway by the process tools where measurement is desired.

8. The wafer measurement system according to claim 6, further including a front handling chamber interior to the front docking port.

9. The wafer measurement system according to claim 8, wherein the front handling chamber is an atmospheric front end (AFE).

10. The fabrication system according to claim 6, wherein the vehicle is able to directly dock with the front docking ports of a process tool.

11. The fabrication system according to claim 6, wherein the vehicle is a personally guided vehicle (PGV).

12. The fabrication system according to claim 6, wherein the vehicle is an automatically guided vehicle (AGV).

13. The fabrication system according to claim 6, wherein the metrology device is an optical measuring device.

14. The fabrication system according to claim 6, wherein the workpiece measurement device is a particle counter.

15. The fabrication system of claim 6, wherein the workpiece holder internally supports the substrate on the edges so as to substantially leave both sides of the substrate exposed for measurement.

16. The fabrication system according to claim 6, wherein the conveyance is a robot arm.

17-36. (canceled)

37. A method of measuring a workpiece in-line as it progresses along a fabrication pathway comprising:
positioning a vehicle, including an integrated metrology device, adjacent to a front docking port of a process tool;
transferring a workpiece using a conveyance from the interior of the process tool into the metrology device;
measuring a feature of the workpiece using the vehicle integrated metrology device;
removing the workpiece from the metrology device; and
transferring the wafer to another component of the fabrication pathway.

38. The method of claim 37, further comprising docking the guided vehicle integrated metrology device with the process tool before transferring the workpiece into the metrology device.

39. The method according to claim 37, wherein the portable metrology device internally supports the workpiece by the edges only so that substantially all of both sides of the workpiece are exposed for measurement.

40. The method according to claim 39, wherein measuring a feature of the workpiece comprises scanning both sides of the workpiece simultaneously comprises measuring both sides of the workpiece without necessitating that the workpiece be subjected to additional movement for this purpose

41. The method according to claim 37, wherein the measuring comprises counting particles on the workpiece.

42-44. (canceled)

45. A method of measuring qualities of a wafer during a fabrication process comprising:
transferring a wafer using a first conveyance from a rear handling chamber into a load lock chamber;
transferring a wafer using a second conveyance from the load lock chamber to a metrology device joined with a front handling chamber;
placing the wafer in a cassette; and
transferring the cassette using a transport to another component of a wafer fabrication pathway.

46. The method of claim 45, wherein the process tool is a cluster tool and the wafer is first transferred from the process chambers of the cluster tool after processing and, then, measured by a metrology device integrated with the front handling chamber.

47. The method according to claim 45, wherein the cassette is a FOUP.

48. The method according to claim 45, wherein the first conveyance is a robot arm.

49. The method according to claim 45, wherein the second conveyance transfers the wafer from inside the load lock chamber to front docking port integrated metrology device.

50. The method according to claim 45, wherein the second conveyance transfers the wafer from inside the load lock chamber to the metrology device integrated into the side of the front handling chamber.

51. The method according to claim 45, wherein the metrology device internally supports the wafer horizontally by the edges only so that substantially all of both sides of the wafer are exposed for measurement.

52. The method according to claim 51, wherein the metrology device is an optical particle counter which simultaneously measures both sides of the wafer without necessitating that the wafer be subjected to additional movement for this purpose.
